(19) United States
(12) Patent Application Publication
(10) Pub. No.: US 2014/0204545 A1
(43) Pub. Date: Jul. 24, 2014

(54) MOUNTING APPARATUS FOR EXPANSION CARD

(71) Applicants: HON HAI PRECISION INDUSTRY CO., LTD., New Taipei (TW); HONG FU JIN PRECISION INDUSTRY (ShenZhen) CO., LTD., Shenzhen (CN)

(72) Inventors: XIANG YU, Shenzhen (CN); XIAO-YONG MA, Shenzhen (CN)

(73) Assignees: HON HAI PRECISION INDUSTRY CO., LTD., New Taipei (TW); HONG FU JIN PRECISION INDUSTRY (ShenZhen) CO., LTD., Shenzhen (CN)

(21) Appl. No.: 13/973,723

(22) Filed: Aug. 22, 2013

(30) Foreign Application Priority Data
Jan. 23, 2013 (CN) 2013100244800

(51) Int. Cl. H05K 7/14

(52) U.S. Cl. CPC H05K 7/1418
USPC 361/759; 248/201

(57) ABSTRACT

A mounting apparatus for mounting an expansion card in an enclosure includes a locating bracket and a locking bracket. The locating bracket includes a protruding portion and a groove. The locking bracket includes a mounting portion and two locking portions. The expansion card includes an abutting bracket. A restricting bracket extends from one end of the abutting bracket. A fixing bracket extends from another end of the abutting bracket. The enclosure includes a locating slot, a mounting hole, and a restricting frame. The restricting bracket is received in the locating slot. The protruding portion is received by the mounting hole. The locating bracket resists against the fixing bracket in the enclosure. The locking bracket is received by the restricting frame. The locking portions resist against the restricting frame. The mounting portion is received in the groove to mount the locking bracket on the computer case.

### BACKGROUND

1. Technical Field

The present disclosure relates to a mounting apparatus for an expansion card.

2. Description of Related Art

Computers can include a number of expansion cards such as video cards, audio cards, and net cards. The expansion cards are mounted on a back plate of the computer case by a number of screws The mounting processes may be laborious and inefficient for installing or removing the cards.

Therefore, there is a need for improvement in the art.

### BRIEF DESCRIPTION OF THE DRAWINGS

Many aspects of the embodiments can be better understood with reference to the following drawings. The components in the drawings are not necessarily drawn to scale, the emphasis instead being placed upon clearly illustrating the principles of the embodiments. Moreover, in the drawings, like reference numerals designate corresponding parts throughout the several views.

FIG. 1 is an isometric, exploded view of an embodiment of a mounting apparatus for expansion cards; the mounting apparatus includes a locating bracket and a locking bracket.

FIG. 2 is an isometric view of the locating bracket of FIG. 1.

FIG. 3 is an assembled view of the mounting apparatus for expansion cards of FIG. 1.

### DETAILED DESCRIPTION

The disclosure is illustrated by way of example and not by way of limitation in the figures of the accompanying drawings in which like references indicate similar elements. It should be noted that references to “an” or “one” embodiment in this disclosure are not necessarily to the same embodiment, and such references mean “at least one.”

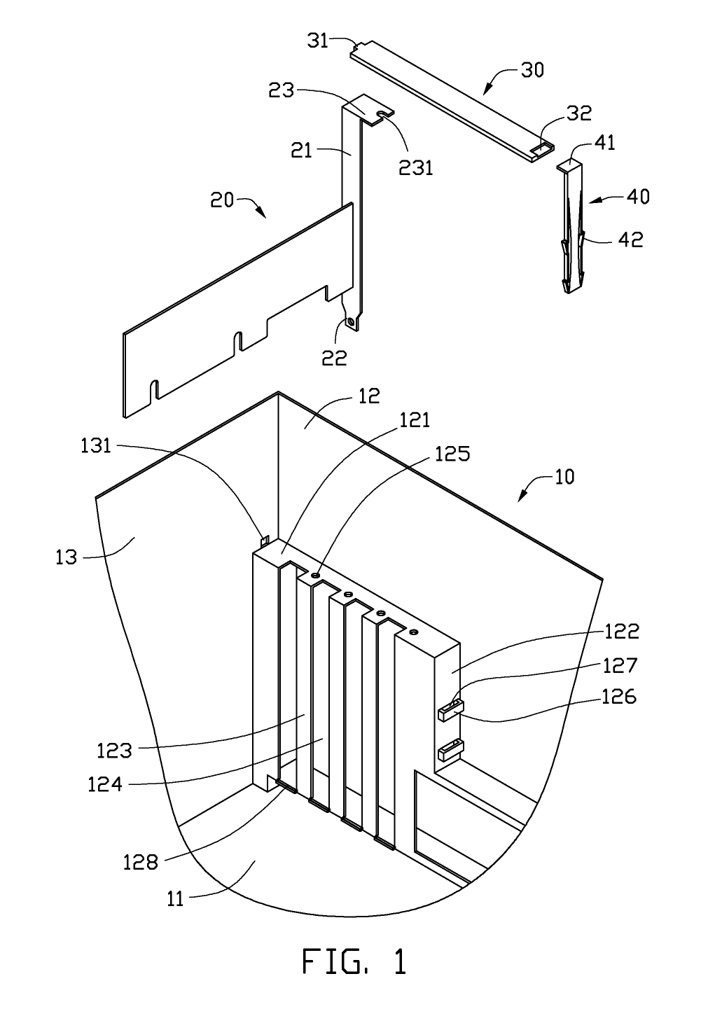

FIG. 1 shows a mounting apparatus for mounting an expansion card 20 on an enclosure 10. The mounting apparatus includes a locating bracket 30 and a locking bracket 40.

The enclosure 10 includes a bottom plate 11, a first side plate 12, and a second side plate 13. The first side plate 12 is connected to the second side plate 13. The first side plate 12 and the second side plate 13 are connected substantially perpendicularly to the bottom plate 11. A first mounting bracket 121 and a second mounting bracket 122 extend substantially perpendicularly from the first side plate 12 to an inside of the enclosure 10. The first mounting bracket 121 is connected to the second mounting bracket 122. A plurality of connecting brackets 123 extends from the first mounting bracket 121 and is connected to the bottom plate 11. The plurality of connecting brackets 123 is connected substantially perpendicularly to the first mounting bracket 121 and the bottom plate 11. An accommodating slot 124 is formed between each two adjacent connecting brackets 123. A plurality of round mounting holes 125 is defined in the first mounting bracket 121. A plurality of restricting frames 126 is defined in the second mounting bracket 122. A restricting slot 127 is defined in each of the plurality of restricting frames 126. A locating slot 128 is defined in the bottom plate 11 between each two adjacent connecting brackets 123. A rectangular restricting hole 131 is defined in the second side plate 13.

An abutting bracket 21 is located on an end of the expansion card 20. A restricting bracket 22 extends from one end of the abutting bracket 21. A fixing bracket 23 extends substantially perpendicularly from another end of the abutting bracket 21. An arc-shaped cutout 231 is defined in the fixing bracket 23. In one embodiment, a width of the abutting bracket 21 is greater than a width of the restricting bracket 22, and a width of the cutout 231 is equal to a diameter of the mounting holes 125.

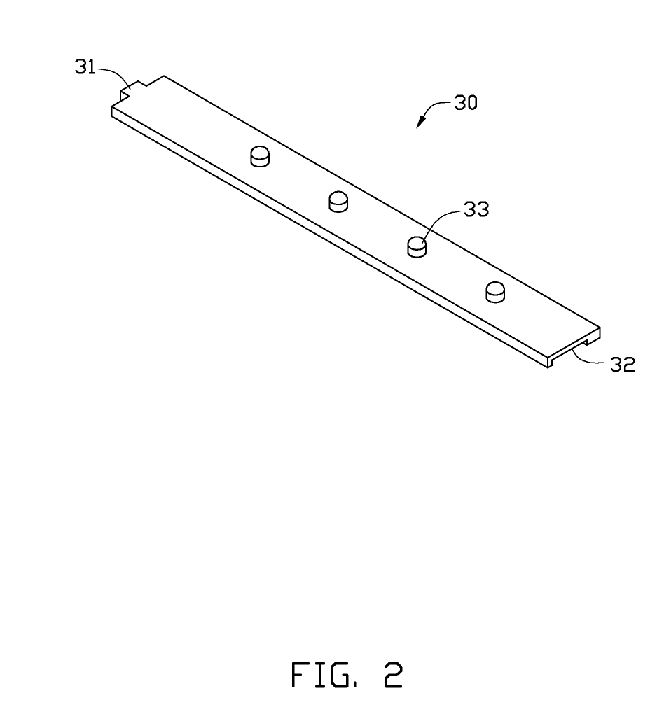

FIGS. 1 and 2 show a restricting portion 31 extending from one end of the locating bracket 30. A groove 32 is defined in another end of the locating bracket 30. A plurality of protruding portions 33 protrude from a side of the locating bracket 30. In one embodiment, a width of the restricting hole 131 is greater than a width of the restricting portion 31, and a width of the locating bracket 30 is greater than a width of the restricting portion 31. The plurality of protruding portions 33 is received by the plurality of round mounting holes 125.

A mounting portion 41 extends substantially perpendicularly from an end of the locking bracket 40. A plurality of locking portions 42 extends from two side edges of the locking bracket 40. In one embodiment, a width of the mounting portion 41 is equal to a width of the groove 32. The plurality of locking portions 42 is elastic. A distance between two adjacent locking portions 42 on two sides of the locking bracket 40 is greater than a width of the restricting slots 127.

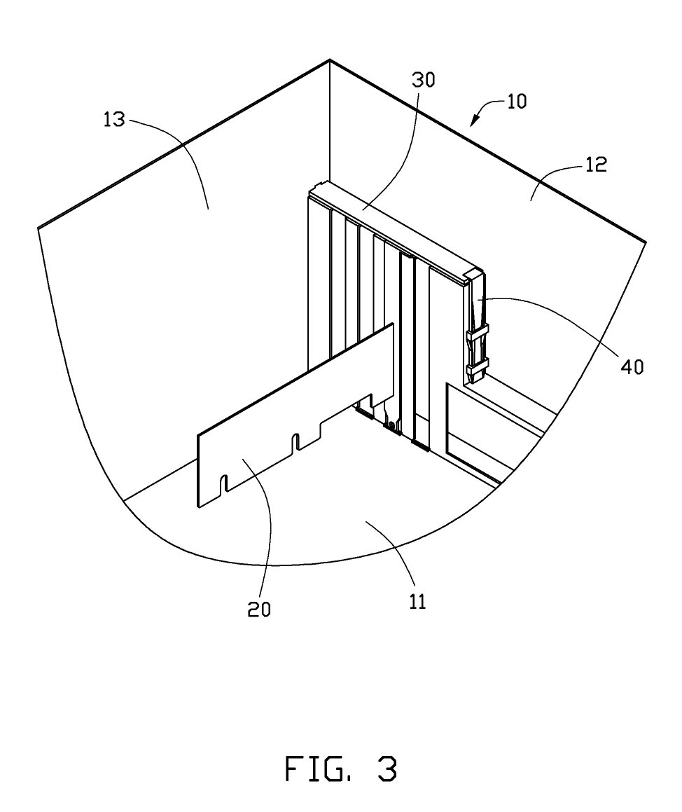

FIGS. 1 to 3 show that in assembly, the restricting bracket 22 of the expansion card 20 is received in the locating slot 128, the cutout 231 is aligned with the corresponding mounting hole 125, and the abutting bracket 21 is received in the corresponding accommodating slot 124. The restricting portion 31 of the locating bracket 30 is received by the restricting hole 131. The plurality of protruding portions 33 is received by the corresponding cutouts 231 and the corresponding mounting holes 125. The locking bracket 40 is received by the restricting slots 127. The locking portions 42 elastically deform to pass through the restricting frames 126, and then elastically return to resist against a bottom of the corresponding restricting frames 126. The mounting portion 41 is received in the groove 32. Therefore, the locating bracket 30 and the locking bracket 40 are mounted on the computer case 10.

In disassembly, the plurality of locking portions 42 is pressed inwards to elastically deform, thereby allowing the locking bracket 40 to be removed from the restricting frames 126. The locating bracket 30 is lifted up from the first mounting bracket 121, and is pulled away from the second side plate 13, thereby detaching the locating bracket 30 from the computer base 10. After the locking bracket 40 and the locating bracket 30 are detached from the computer base 10, the expansion card 20 is lifted up from the bottom plate 11.

Even though numerous characteristics and advantages of the present disclosure have been set forth in the foregoing description, together with details of the structure and function of the disclosure, the disclosure is illustrative only, and changes may be made in detail, especially in the matters of shape, size, and the arrangement of parts within the principles of the disclosure to the full extent indicated by the broad general meaning of the terms in which the appended claims are expressed.

What is claimed is:

1. A mounting apparatus for mounting an expansion card on an enclosure, comprising:
a locating bracket comprising a protruding portion and a groove; and
a locking bracket comprising a mounting portion and two locking portions; wherein the expansion card comprises an abutting bracket; a restricting bracket extends from one side of the abutting bracket; a fixing bracket extends from another side of the abutting bracket; the enclosure comprises a locating slot, a mounting hole, and a restricting frame; the restricting bracket is received in the locating slot; the protruding portion passes through the mounting hole; the locating bracket resists against the fixing bracket on the enclosure; the locking bracket passes through the restricting frame; the locking portions resist against the restricting frame; and the mounting portion is received in the groove to mount the locking bracket on the computer case.

2. The mounting apparatus of claim 1, wherein the restricting frame comprises a restricting slot; and the locking bracket passes through the restricting slot to mount on the computer case.

3. The mounting apparatus of claim 2, wherein the protruding portion is interference engaged with the mounting hole; a width of the mounting portion is equal to a width of the groove; and a distance between the two locking portions is greater than a width of the restricting slot.

4. The mounting apparatus of claim 1, wherein the enclosure comprises a restricting hole; a restricting portion extends from the locating bracket; and the restricting portion passes through the restricting hole to mount the locating bracket on the enclosure.

5. The mounting apparatus of claim 4, wherein a width of the restricting hole is greater than a thickness of the restricting portion; and a width of the locating bracket is greater than a width of the restricting portion.

6. The mounting apparatus of claim 1, wherein the fixing bracket comprises a cutout; the cutout is aligned to the mounting hole when the abutting bracket is mounted on the enclosure; and the protruding portion passes through the cutout and is received in the mounting hole.

7. The mounting apparatus of claim 6, wherein a width of the abutting bracket is greater than a width of the restricting bracket; and a width of the cutout is equal to a diameter of the mounting hole.

8. The mounting apparatus of claim 1, wherein the locking portions are elastic brackets.

9. A mounting apparatus for mounting an expansion card on an enclosure, comprising:
an expansion card comprising an abutting bracket; wherein a restricting bracket extends from one side of the abutting bracket; a fixing bracket extends from another side of the abutting bracket;
an enclosure comprising a locating slot, a mounting hole, and a restricting frame;
a locating bracket comprising a protruding portion and a groove; and
a locking bracket comprising a mounting portion and two locking portions; wherein the restricting bracket is received in the locating slot; the protruding portion passes through the mounting hole; the locating bracket resists against the fixing bracket on the enclosure; the locking bracket passes through the restricting frame; the locking portions resist against the restricting frame; and the mounting portion is received in the groove to mount the locking bracket on the computer case.

10. The mounting apparatus of claim 9, wherein the restricting frame comprises a restricting slot; and the locking bracket passes through the restricting slot to mount on the computer case.

11. The mounting apparatus of claim 10, wherein the protruding portion is interference engaged with the mounting hole; a width of the mounting portion is equal to a width of the groove; and a distance between the two locking portions is greater than a width of the restricting slot.

12. The mounting apparatus of claim 9, wherein the enclosure comprises a restricting hole; a restricting portion extends from the locating bracket; and the restricting portion passes through the restricting hole to mount the locating bracket on the enclosure.

13. The mounting apparatus of claim 12, wherein a width of the restricting hole is greater than a thickness of the restricting portion; and a width of the locating bracket is greater than a width of the restricting portion.

14. The mounting apparatus of claim 9, wherein the fixing bracket comprises a cutout; the cutout is aligned to the mounting hole when the abutting bracket is mounted on the enclosure; and the protruding portion passes through the cutout and is received in the mounting hole.

15. The mounting apparatus of claim 14, wherein a width of the abutting bracket is greater than a width of the restricting bracket; and a width of the cutout is equal to a diameter of the mounting hole.

16. The mounting apparatus of claim 9, wherein the locking portions are elastic brackets.
